(19) United States
(12) Patent Application Publication
(10) Pub. No.: US 2013/0062737 A1
(43) Pub. Date: Mar. 14, 2013

(54) SEMICONDUCTOR DEVICE AND MANUFACTURING METHOD OF THE SAME

(71) Applicants: Satoshi HONGO, Oita-shi (JP); Kazumasa Tanida, Oita-shi (JP); Kenji Takahashi, Tsukuba-shi (JP)

(72) Inventors: Satoshi HONGO, Oita-shi (JP); Kazumasa Tanida, Oita-shi (JP); Kenji Takahashi, Tsukuba-shi (JP)

(21) Appl. No.: 13/428,424

(22) Filed: Mar. 23, 2012

(30) Foreign Application Priority Data
Sep. 13, 2011 (JP) 2011-199951

(51) Int. Cl. H01L 29/06; H01L 21/78

(52) U.S. Cl. 257/622; 438/462; 257/E29.022; 257/E21.599

(57) ABSTRACT

According to one embodiment, a semiconductor device comprises a device substrate, and a supporting substrate. The supporting substrate is joined onto the device substrate. The device substrate has a first groove in an outer circumferential portion on a joint surface side to the supporting substrate.

### CROSS-REFERENCE TO RELATED APPLICATIONS

This application is based upon and claims the benefit of priority from prior Japanese Patent Application No. 2011-199951, filed Sep. 13, 2011, the entire contents of which are incorporated herein by reference.

### FIELD

Embodiments described herein relate generally to a semiconductor device and a method of manufacturing the semiconductor device.

### BACKGROUND

In recent years, CMOS (Complementary Metal Oxide Semiconductor) image sensors have been proposed and commercially used as solid state image sensors used in digital still cameras and the like. Features of the CMOS image sensor include the single power supply, low voltage drive, and low power consumption.

The pixel size of the CMOS image sensor becomes smaller year after year due to demands of an increasing number of pixels and a decreasing optical size. For example, the pixel size of a CMOS image sensor used in a digital still camera is about 2 μm to 3 μm. If microstructures become still finer in CMOS image sensors, a problem of lower sensitivity due to a smaller opening through which light passes between wires is caused.

To address this problem, a backside illumination CMOS image sensor having a signal scanning circuit and a wiring layer (circuit unit) thereof on a front side of a semiconductor substrate and having a light receiving surface on the opposite side (back side) of the circuit portion has been developed. By using this structure, sensitivity of a CMOS image sensor can be increased.

In a backside illumination CMOS image sensor, a device wafer (device substrate) in which a wiring layer is formed and a support wafer (supporting substrate) are pasted by a direct junction method and then, a chip is cut by a dicing process.

Due to a pasting process, a guard ring cannot be formed on an inner side of a dicing line (inner side of the chip) in an interface layer of pasting. Thus, film peeling due to horizontal cracks occurs during dicing in the interface layer between the device wafer and the support wafer, increasing unacceptable chips to lower yields.

In contrast, a technique (laser grouping) of providing a groove inside the diving line in advance by laser before dicing is used. Problems of laser grouping include contamination due to debris scattering during laser machining, a long machining time, and high costs. Particularly, debris scattering is fatal for sensor products and adhesion of debris to a pixel area makes the chip unacceptable. Techniques of forming a protective layer to suppress debris scattering before tuning of a film structure and laser grouping are known, but such techniques cause an increase in cost.

### BRIEF DESCRIPTION OF THE DRAWINGS

FIG. 1 is a plan view showing a structure of a semiconductor device according to a first embodiment;

FIG. 2 is a sectional view showing the structure of the semiconductor device according to the first embodiment;

FIGS. 3, 4, 5, 6, 7, 8, 9, 10, 11, 12, 13, 14, 15, 16, 17, 18, 19, 20, 21, 22, and 23 are sectional views showing steps of manufacturing the semiconductor device according to the first embodiment;

FIG. 24 is a sectional view showing the structure of a semiconductor device according to a second embodiment;

FIG. 25 is a sectional view showing the structure of a semiconductor device according to a third embodiment;

FIG. 26 is a sectional view showing the structure of a semiconductor device according to a fourth embodiment; and

FIG. 27 is a sectional view showing the structure of a semiconductor device according to a fifth embodiment.

### DETAILED DESCRIPTION

In general, according to one embodiment, a semiconductor device comprises a device substrate; and a supporting substrate. The supporting substrate is joined onto the device substrate. The device substrate has a first groove in an outer circumferential portion on a joint surface side to the supporting substrate.

The present embodiment will be described below with reference to drawings. In the drawings, the same reference numerals are attached to the same portions. A duplicate description will be provided if necessary.

### First Embodiment

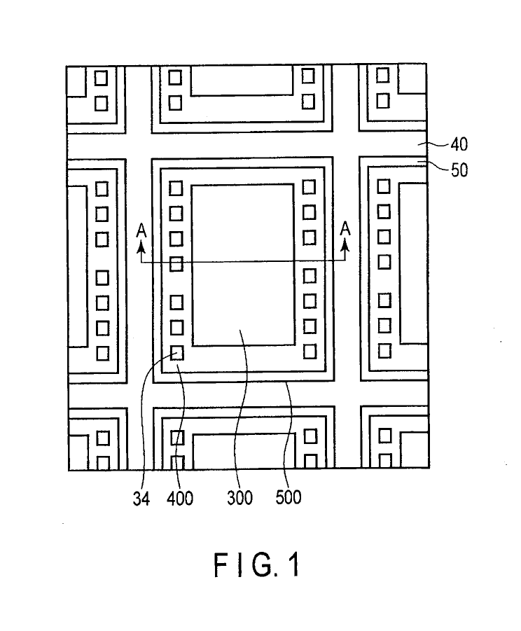

A semiconductor device (backside illumination CMOS image sensor) according to the first embodiment will be described using FIGS. 1, 2, 3, 4, 5, 6, 7, 8, 9, 10, 11, 12, 13, 14, 15, 16, 17, 18, 19, 20, 21, 22, and 23. The semiconductor device according to the first embodiment is an example in which a device wafer (device substrate) 600 has a groove 50 on an inner side of a dicing line (center side of a chip 500) on a joint surface side to a supporting wafer (supporting substrate) 200. Accordingly, an occurrence of horizontal cracks to the device substrate 600 during dicing process can be prevented so that damage to the chip 500 can be reduced. The first embodiment will be described in detail below.

### [Structure]

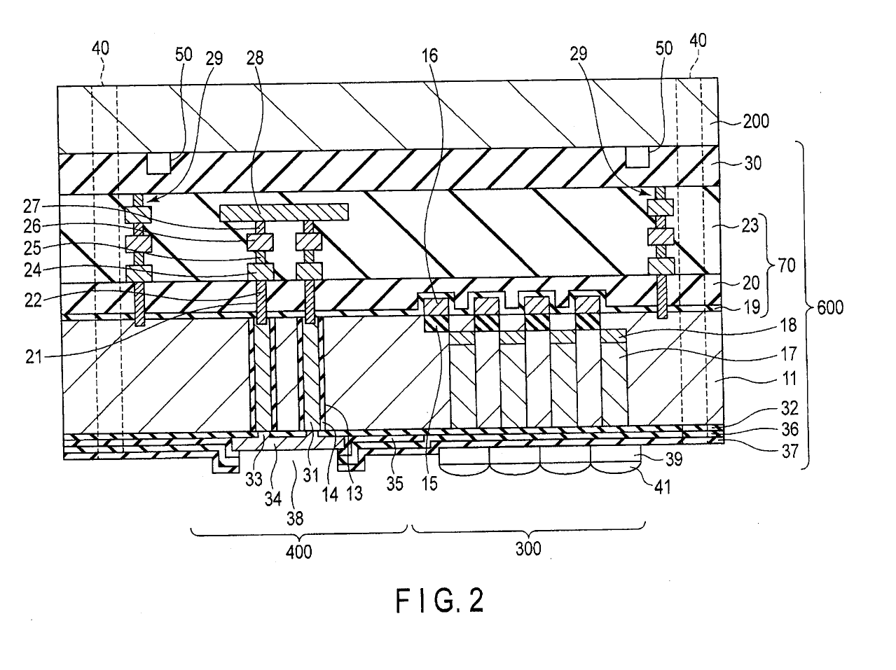

First, the structure of a semiconductor device according to the first embodiment will be described using FIGS. 1 and 2.

FIG. 1 is a plan view showing the structure of a semiconductor device according to the first embodiment. FIG. 1 shows a wafer before dicing and shows a plurality of chips.

As shown in FIG. 1, the semiconductor device according to a first embodiment comprises the chip 500 divided by a dicing line 40.

The chip 500 includes a pixel region 300 positioned in a center portion and a peripheral region 400 positioned in a periphery thereof. The pixel region 300 has a light receiving unit (photo-diode) that stores charges by making a signal conversion of illuminated light. The peripheral region 400 has a circuit to process a signal from the pixel region 300 and a circuit to control an operation of the pixel region. The peripheral region 400 also has a pad 34 for external electric connection.

In the first embodiment, the device substrate 600 described later has the groove 50 in the inner side of the dicing line 40 in a joint surface (interface) with the supporting substrate 200 in the chip 500. In other words, the groove 50 is formed in an outer circumferential portion of the chip 500 as if to surround a circumference thereof. A section structure of the groove 50 will be described in detail later.

FIG. 2 is a sectional view showing the structure of the semiconductor device according to the first embodiment and a sectional view along an A-A line shown in FIG. 1. While the peripheral region 400 is formed adjacent to one side of the pixel region 300 in FIG. 2, the peripheral region 400 may be formed also adjacent to the other side thereof. In the description that follows, the upper and lower relations are as shown in drawings.

As shown in FIG. 2, the semiconductor device according to the first embodiment comprises the device substrate 600 having a semiconductor layer 11, a wiring layer 70, and an insulating layer 30 and the supporting substrate 200 joined onto the device substrate 600.

In the device substrate 600, the wiring layer 70 having a circuit unit is formed on a front side (upper surface in FIG. 2) of the semiconductor layer 11. A color filter 39, a microlens 41, and the pad 34 are formed on a back side (lower surface in FIG. 2) of the semiconductor layer 11. A photo-diode is also formed inside the semiconductor layer 11. That is, a backside illumination CMOS image sensor stores charges inside the semiconductor layer 11 by making a signal conversion of light illuminated from the back side of the semiconductor layer 11 and reads stored charges to the wiring layer 70 on the front side. Each structural element will be described below.

The semiconductor layer 11 is, for example, an N-type Si epitaxial layer. The semiconductor layer 11 has an active layer formed by introducing impurities and a photo-diode and a transistor described later are formed in this region.

In the pixel region 300, an N-type impurity layer 17 and a P-type impurity layer 18 are formed inside the semiconductor layer 11. The N-type impurity layer 17 is formed in a deep region (lower region in FIG. 2) inside the semiconductor layer 11, the P-type impurity layer 18 is formed in a shallow region (upper region in FIG. 2) inside the semiconductor layer 11, and both layers are formed in contact with each other. The N-type impurity layer 17 and the P-type impurity layer 18 are in each pixel to constitute a photo-diode. An element isolation insulating layer 15 is formed between adjacent pixels inside the semiconductor layer 11 on the front side. The element isolation insulating layer 15 is formed of, for example, SiO₂.

Also in the pixel region 300, a gate electrode 16 is formed for each pixel on the front side of the semiconductor layer 11 to constitute, for example, a transfer transistor or a reset transistor. The gate electrode 16 is formed of, for example, polysilicon. The surface of the gate electrode 16 is covered with an insulating layer 19. An interlayer insulating layer 20 whose upper surface is planarized is formed on the insulating layer 19.

Also in the pixel region 300, the color filter 39 is formed on the back side of the semiconductor layer 11 via an insulating layer 32 and antireflection layers 36, 37. The microlens 41 is formed below the color filter 39. The color filter 39 and the microlens 41 are formed for each pixel and formed corresponding to the photo-diode.

In the peripheral region 400, a groove (DT: Deep Trench) 13 passing from the upper surface to the lower surface thereof is formed inside the semiconductor layer 11. An insulating layer 14 is formed on the side surface of the groove 13. A penetrating electrode 31 is formed on the insulating layer 14 to fill up the groove 13.

Also in the peripheral region 400, an embedded electrode (via) 22 electrically connected to the penetrating electrode 31 is formed on the front side of the semiconductor layer 11. The embedded electrode 22 is formed inside a via hole 21 formed inside the insulating layer 19 and the interlayer insulating layer 20. A wire 24, an embedded electrode 25, a wire 26, an embedded electrode 27, and a wire 28 constituting a circuit that processes a signal from the pixel region 300 and a circuit that controls the operation of the pixel region (circuit unit) are formed one by one on the embedded electrode 22. The wire 24, the embedded electrode 25, the wire 26, the embedded electrode 27, and the wire 28 are formed inside an interlayer insulating layer 23 formed on the interlayer insulating layer 20.

Also in the peripheral region 400, the pad 34 electrically connected to penetrating electrode 31 is formed on the back side of the semiconductor layer 11. The pad 34 is electrically connected to penetrating electrode 31 through an opening 33 formed in the insulating layer 32. The pad 34 is also electrically connected to an external electrode (not shown) through an opening 38 formed in an insulating layer 35 and the antireflection layers 36, 37.

That is, in the peripheral region 400, the circuit unit formed on the front side and the pad 34 formed on the back side are electrically connected via the penetrating electrode 31.

The device substrate 600 has a guard ring 29 in the outer circumferential portion of the chip 500. More specifically, the guard ring 29 is formed inside the interlayer insulating layer 20 and the interlayer insulating layer 23 in the outer circumferential portion of the chip 500. The guard ring 29 is formed of vias and wires of the same level as vias and wires of the embedded electrode 22, the wire 24, the embedded electrode 25, the wire 26, the embedded electrode 27, and the wire 28 and surrounds the circumference of the chip 500. The guard ring 29 is formed on the inner side (center side of the chip 500) from the dicing line 40. The guard ring 29 can prevent cracks in the wiring layer 70 from being generated during dicing process.

In the first embodiment, the device substrate 600 has the insulating layer 30 on the wiring layer 70 as a joint surface to the supporting substrate 200. The insulating layer 30 is formed of, for example, an oxide film. More specifically, the insulating layer 30 is formed of, for example, silicon oxide film (SiO₂ film) using TEOS or the like as a material or a low-k film. The thickness of the insulating layer 30 is, for example, 0.1 μm or more and 5 μm or less.

The supporting substrate 200 is joined onto the insulating layer 30. That is, below the supporting substrate 200, the wiring layer 70 and the semiconductor layer 11 are formed via the insulating layer 30 one by one. The supporting substrate 200 and the insulating layer 30 are joined by both being pressurized. The supporting substrate 200 may be formed of a semiconductor substrate of Si or the like or an insulating substrate of glass, ceramics, resin or the like.

The insulating layer 30 has the groove 50 in the outer circumferential portion of the chip 500. More specifically, the insulating layer 30 has the groove 50 in the outer circumferential portion of the chip 500 on the joint surface side (upper surface side) to the supporting substrate 200. That is, the groove 50 is formed in contact with the supporting substrate 200. In other words, the insulating layer 30 is not in contact with the supporting substrate 200 in a position where the groove 50 is formed. The groove 50 may not only be formed on the joint surface side to the supporting substrate 200, but also extend through the insulating layer 30 up to the side of the wiring layer 70.

The groove 50 is positioned on the inner side from the dicing line 40. The groove 50 is formed just above the guard ring 29 or on the inner side from just above, but the groove 50 is preferably formed just above the guard ring 29 to reduce the area of the chip 500.

The width (width in the plane) of the groove 50 is narrower than the width of the dicing line 40. More specifically, the width of the groove 50 is about a few μm and the width of the dicing line 40 is about 100 μm. The depth (depth in a direction perpendicular to the plane) of the groove 50 is, for example, 0.1 μm or more and 5 μm or less, thereby preventing an occurrence of cracks.

The groove 50 may be hollow or filled with a material that is different from the material therearound. Materials with which the groove 50 is filled include, for example, materials that are not joined such as SiN (silicon nitride), metallic materials such as Cu and Al, and insulating materials such as silicon oxide (SiO₂ film) using TEOS or the like as a material.

### [Manufacturing Method]

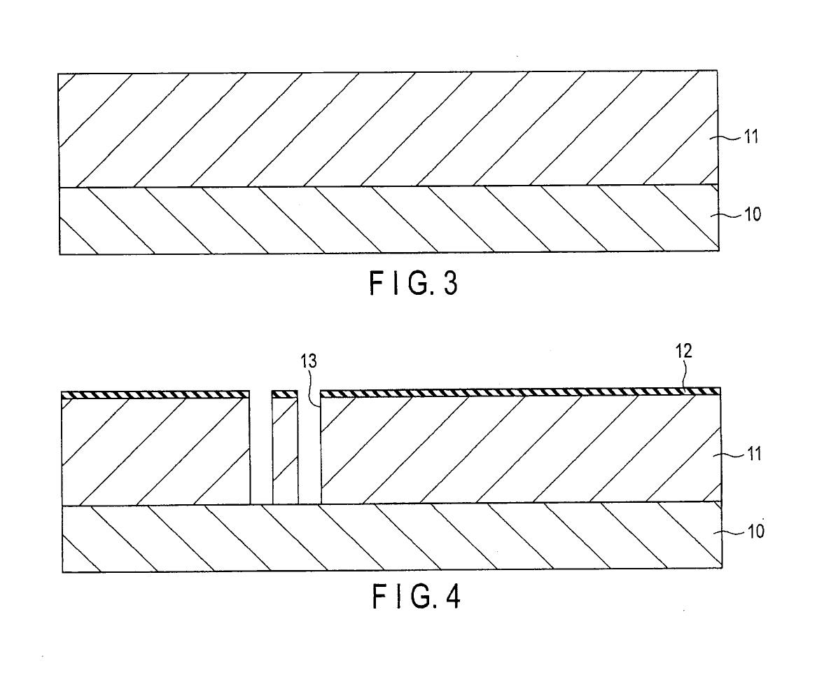

Next, the method for manufacturing a semiconductor device according to the first embodiment will be described using FIGS. 3, 4, 5, 6, 7, 8, 9, 10, 11, 12, 13, 14, 15, 16, 17, 18, 19, 20, 21, 22, and 23.

FIGS. 3, 4, 5, 6, 7, 8, 9, 10, 11, 12, 13, 14, 15, 16, 17, 18, 19, 20, 21, 22, and 23 are sectional views showing steps of manufacturing the semiconductor device according to the first embodiment. In the description that follows, the upper and lower relations are as shown in drawings, but some manufacturing processes may be performed in an upside-down state.

First, as shown in FIG. 3, the semiconductor layer 11 is formed on a semiconductor substrate 10, which is an SOI substrate or bulk substrate, by epitaxial growth. The semiconductor layer 11 is, for example, an N-type Si epitaxial layer.

Next, as shown in FIG. 4, a stopper layer 12 is formed on the semiconductor layer 11 by, for example, the CVD (Chemical Vapor Deposition) method. The stopper layer 12 is formed of, for example, SiN. Then, the groove 13 is formed in the stopper layer 12 and the semiconductor layer 11 by, for example, photolithography and dry etching. The groove 13 is a through hole passing from the upper surface to the lower surface of the semiconductor layer 11. Accordingly, the upper surface of the semiconductor substrate 10 is exposed at the bottom of the groove 13.

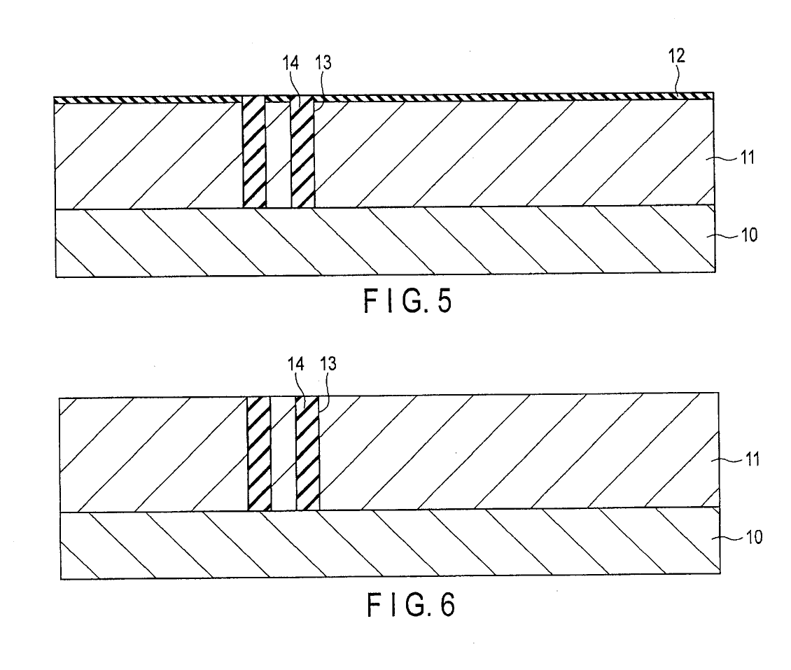

Next, as shown in FIG. 5, the insulating layer 14 is formed on the entire surface by, for example, the CVD method. Accordingly, the insulating layer 14 is embedded in the groove 13 and also formed on the stopper layer 12. The insulating layer 14 is formed of, for example, SiO₂. Then, the insulating layer 14 on the stopper layer 12 is removed by, for example, CMP (Chemical Mechanical Polishing).

Next, as shown in FIG. 6, the stopper layer 12 is removed by, for example, wet etching. Accordingly, the upper surface of the semiconductor layer 11 is exposed. In this case, various kinds of etching may be used, but wet etching is desirably used to prevent damage to the upper surface of the semiconductor layer 11.

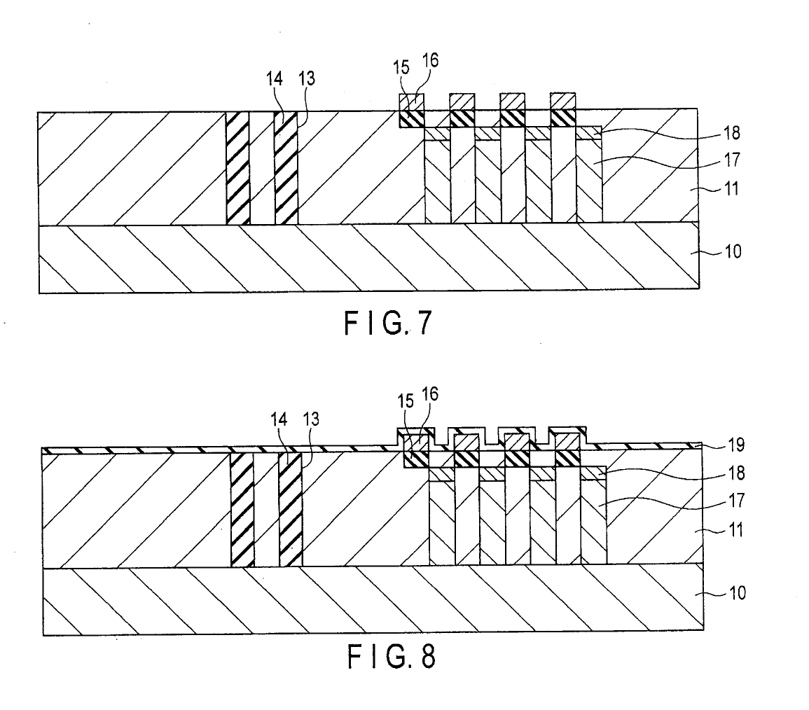

Next, as shown in FIG. 7, after the element isolation insulating layer 15 being embedded between pixels inside the semiconductor layer 11 on the upper surface side, the gate electrode 16 is formed on the upper surface of the semiconductor layer 11 for each pixel. The element isolation insulating layer 15 is formed of, for example, SiO₂ and the gate electrode 16 is formed of, for example, polysilicon.

Then, the N-type impurity layer 17 is formed in a deep region (region on the lower surface side) inside the semiconductor layer 11 by ion implantation of impurities such as P and As into the semiconductor layer 11. Further, the P-type impurity layer 18 is formed in a shallow region (region on the upper surface side) by ion implantation of impurities such as B into the semiconductor layer 11. With the P-type impurity layer 18 being formed on the N-type impurity layer 17, a photo-diode is formed for each pixel as a photoelectric conversion unit.

Before the gate electrode 16 being formed on the semiconductor layer 11, the N-type impurity layer 17 and the P-type impurity layer 18 may be formed inside the semiconductor layer 11.

In this manner, a transistor or photo-diode is formed in an active layer by the FEOL (Front End Of Line) process.

Next, as shown in FIG. 8, the insulating layer 19 is formed on the gate electrode 16 and the semiconductor layer 11 by thermal oxidation or the CVD method. The thickness of the insulating layer 19 is, for example, 5 nm or more and 6 nm or less. The insulating layer 19 is formed of, for example, SiO₂.

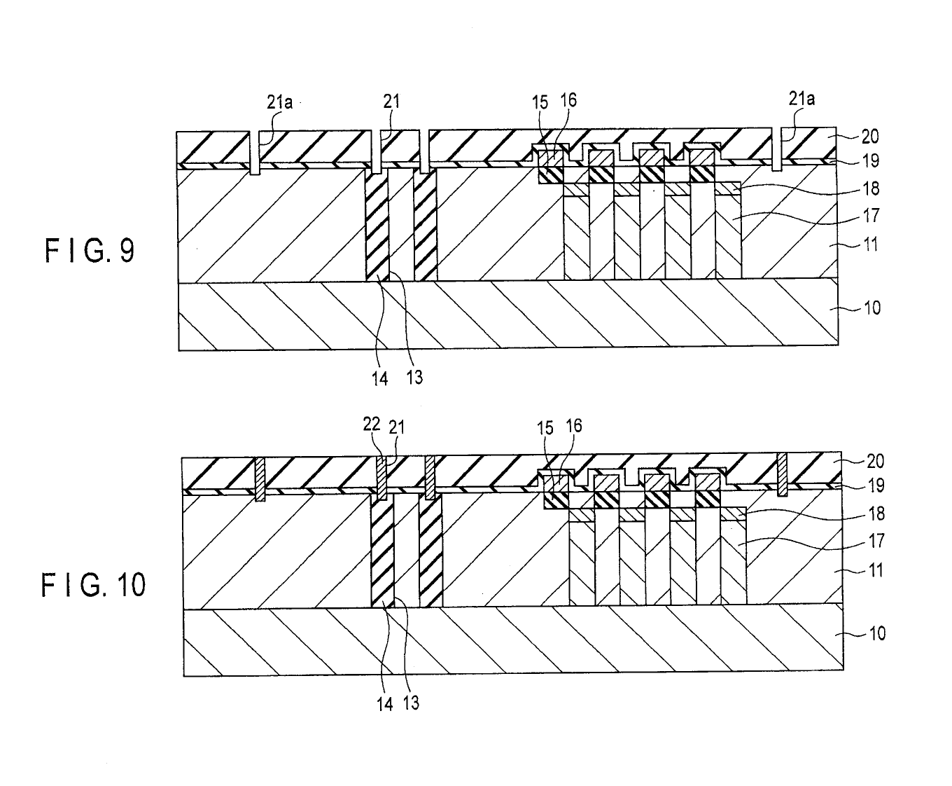

Next, as shown in FIG. 9, the interlayer insulating layer 20 is formed on the entire surface by, for example, the CVD method and the upper surface thereof is planarized. Then, the opening 21 is formed in the interlayer insulating layer 20 and the insulating layer 19 by, for example, photolithography and dry etching so that the insulating layer 14 is exposed. Simultaneously with the opening 21, an opening 21a is also formed in the interlayer insulating layer 20 and the insulating layer 19 in the outer circumferential portion of the chip. The opening 21a is formed in a region where the guard ring 29 described later is formed.

The interlayer insulating layer 20 is formed of, for example, SiO₂. If the insulating layer 19 and the interlayer insulating layer 20 are formed of the same material, the insulating layer 19 and the interlayer insulating layer 20 can integrally be formed.

Next, as shown in FIG. 10, the embedded electrode 22 is formed on the entire surface by, for example, the CVD method. Accordingly, the embedded electrode 22 is embedded in the opening 21 and the opening 21a. At the same time, the embedded electrode 22 is also formed on the interlayer insulating layer 20. The embedded electrode 22 is formed of, for example, W, Al, or Cu. Then, the embedded electrode 22 on the interlayer insulating layer 20 is removed by, for example, CMP.

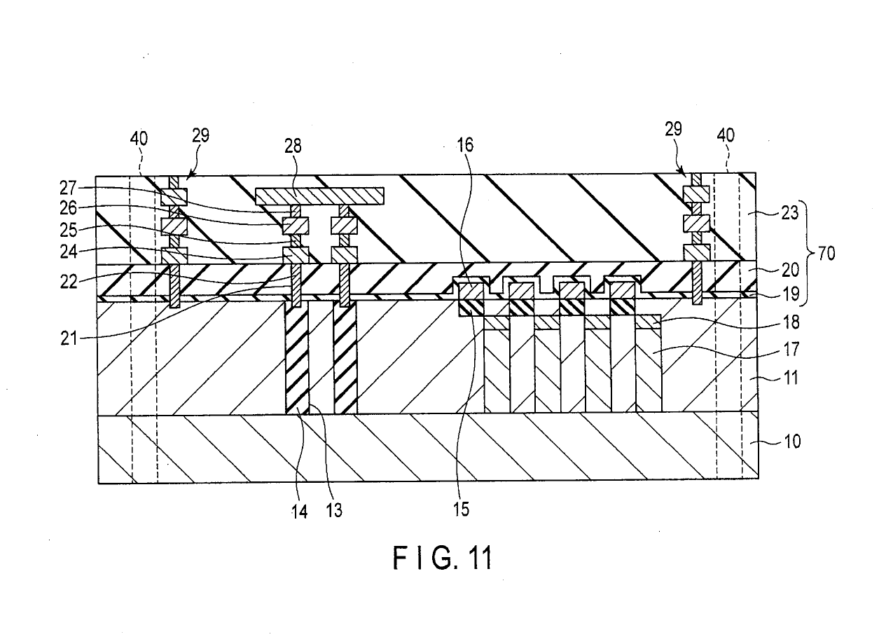

Next, as shown in FIG. 11, the interlayer insulating layer 23 is formed on the interlayer insulating layer 20 by, for example, the CVD method and also the embedded wires 24, 26, 28 and the embedded electrodes 25, 27 are formed inside the interlayer insulating layer 23. The wires 24, 26, 28 are formed of, for example, Al or Cu and the embedded electrodes 25, 27 are formed of, for example, W, Al, or Cu. In this case, the wires 24, 26, 28 may be formed in a damascene structure with a single damascene or dual damascene.

Simultaneously with the wires 24, 26, 28 and the embedded electrodes 25, 27, the guard ring 29 is also formed inside the interlayer insulating layer 23 in the outer circumferential portion of the chip 500. The guard ring 29 is formed at the same level as the wires 24, 26, 28 and the embedded electrodes 25, 27 and formed of the same material. The guard ring 29 is formed on the inner side (center side of the chip 500) from the dicing line 40. The guard ring 29 can prevent cracks in the chip 500 from being generated during dicing process.

In this manner, the wiring layer 70 mutually connecting a transistor or photo-diode is formed by the BEOL (Back End Of Line) process.

Then, the upper surface of the interlayer insulating layer 23 is planarized by CMP. If the wires 24, 26, 28 are formed in a damascene structure, there is no need to planarize the uppermost surface because the upper surface is planarized each time.

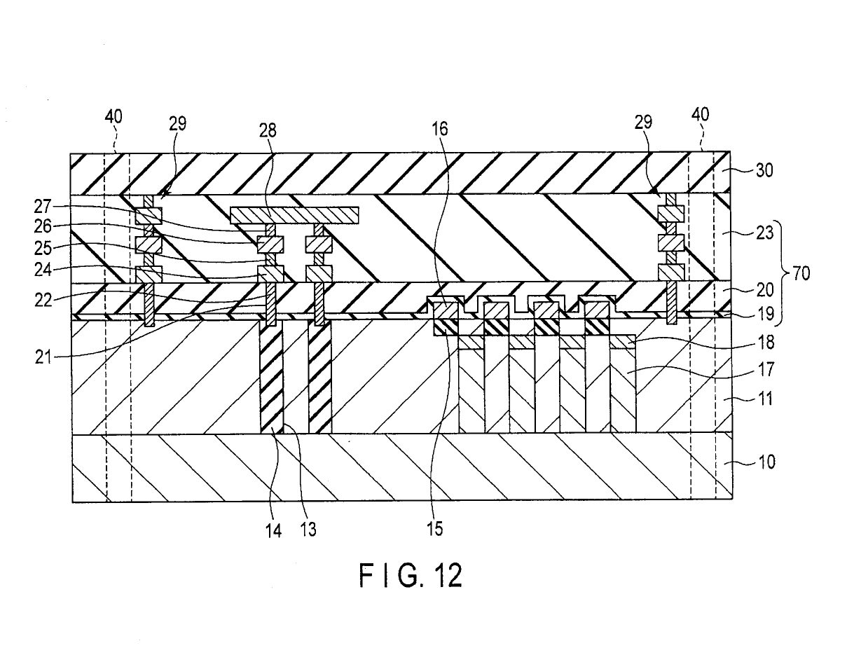

Next, as shown in FIG. 12, the insulating layer 30 is formed on the interlayer insulating layer 23. The insulating layer 30 is formed of, for example, an oxide film and more specifically, an SiO₂ film using TEOS or the like as a material or a low-k film. The insulating layer 30 is formed by various methods such as the CVD method, the ALD (Atomic Layer Deposition) method, an application process or the like.

Then, the upper surface of the insulating layer 30 is planarized by, for example, CMP. The upper surface of the insulating layer 30 becomes the joint surface to the supporting substrate 200 described later. By planarizing the upper surface of the insulating layer 30, the bonding strength between the insulating layer 30 and the supporting substrate 200 can be improved.

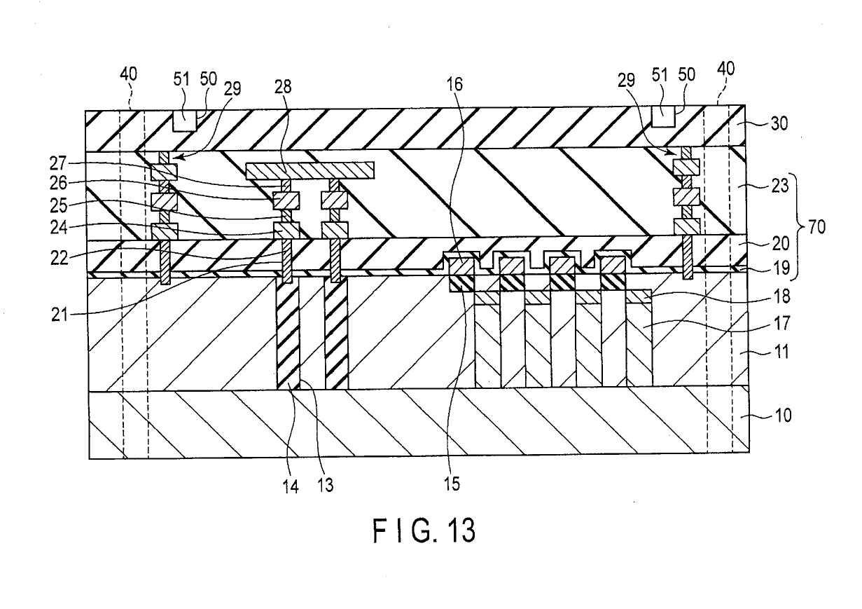

Next, as shown in FIG. 13, the groove 50 is formed on the upper surface side of the insulating layer 30 by, for example, photolithography and dry etching. The groove 50 is formed in the outer circumferential portion of the chip 500 and on the inner side from the dicing line 40. The groove 50 is also formed just above the guard ring 29 or on the inner side from just above.

The groove 50 is structured so that no flake or film peeling occurs in the semiconductor layer 11 and the wiring layer 70 in the polishing process of the semiconductor substrate 10 described later. More specifically, the width of the groove 50 is about a few μm and the depth thereof is, for example, 0.1 μm or more and 5 μm or less. The groove 50 may be hollow or filled up. Materials with which the groove 50 is filled include, for example, materials that are not joined such as SiN, metallic materials such as Cu and Al, and insulating materials such as TEOS.

Then, the upper surface of the insulating layer 30 may be planarized by, for example, the CMP method. The upper surface of the insulting layer 30 needs only to be planarized at least before or after formation of the groove 50.

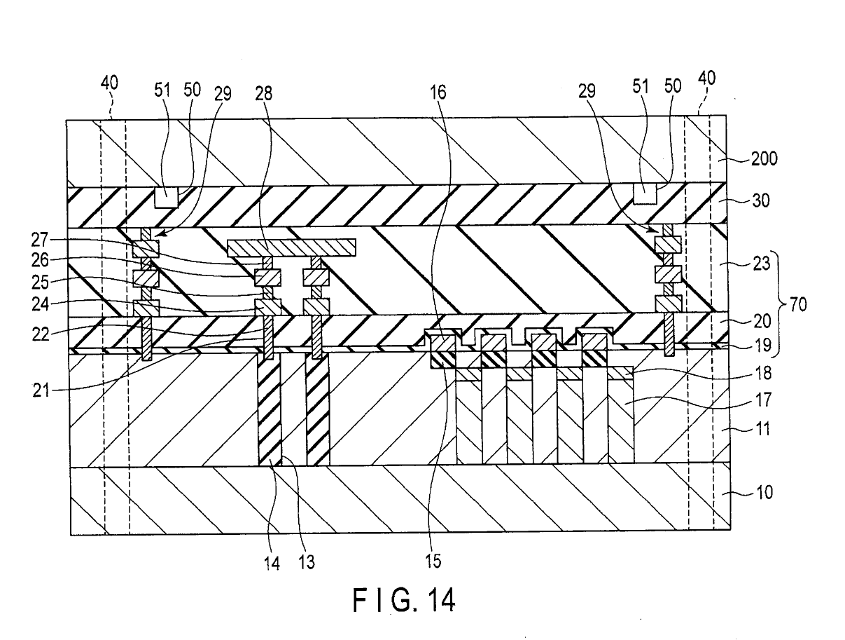

Next, as shown in FIG. 14, the supporting substrate 200 is joined onto the insulating layer 30 in which the groove 50 is formed by pasting. The pasting process is performed as follows.

First, before pasting, the joint surface of each of the insulating layer 30 and the supporting substrate 200 is cleaned. More specifically, an alkali cleaning or acid cleaning to remove metallic contamination and an O₃ cleaning to remove organic matter are done to the joint surface. In addition, a binary fluid cleaning or megasonic cleaning may be done to remove dust.

Next, the joint surface of each of the insulating layer 30 and the supporting substrate 200 is activated. More specifically, the joint surface is plasma-treated by an ion beam, ion gun, or RIE (Reactive Ion Etching). The treatment is provided by using a gas such as Ar, N₂, O₂, and H₂ and under conditions under which the joint surface is less likely to be damaged. The gas may be a single gas or a mixed gas.

Next, the joint surface of each of the insulating layer 30 and the supporting substrate 200 is re-cleaned. More specifically, a cleaning that does not damage the activation layer such as a binary fluid cleaning, megasonic cleaning, and water cleaning is done to remove dust stuck in the activation process. If the activation to pasting processes are performed successively in a vacuum or cleanliness of the activation to pasting processes is sufficiently high, the re-cleaning process may be omitted.

Next, the joint surface of the insulating layer 30 and the joint surface of the supporting substrate 200 are pasted together. More specifically, after the device substrate 600 and the supporting substrate 200 being aligned without misregistration, the device substrate 600 and the supporting substrate 200 are pressurized so that a bonding wave of spontaneous bonding develops concentrically for pasting together. In this case, mechanical, outline recognition, and mark matching methods and the like are used for alignment and the alignment needs to be with precision to μm or higher. After the insulating layer 30 and the supporting substrate 200 being pasted together, misregistration measurements of substrates are made and voids are checked for to investigate the precision of pasting if necessary. The transparent mode outline detection or reflection mode edge detection is used for misregistration measurements. Infrared rays, ultrasonic waves, or X rays are used to check for voids.

Then, the pasted joint surfaces are annealed, for example, at a high temperature of 200° C. or higher and 1000° C. or lower for several hours to increase bonding strength. In general, the bonding strength tends to increase with an increasing temperature at which the pasted joint surfaces are annealed. However, if heat resistance of the material formed in the FEOL process is considered, characteristics may be degraded by annealing at about 0° C. for several hours. Thus, the annealing is performed, for example, at 300° C. in an N₂ atmosphere. Accordingly, the bonding of the joint surfaces can be changed to the stronger Si—O bonding. Incidentally, if the pasting strength is sufficiently high, annealing may be omitted, performed at a lower temperature, or performed for a shorter time.

The supporting substrate 200 may be formed of a semiconductor substrate of Si or the like or an insulating substrate of glass, ceramics, resin or the like. The supporting substrate 200 may be raw before joining with the entire surface thereof exposed, but the upper surface and side surface thereof may be covered with a protective film (not shown) formed of SiN to protect the exposed surface. In such a case, the entire surface (upper surface, side surface, and lower surface) of the supporting substrate 200 is covered with the protective film and the joint surface (lower surface) is exposed by RIE or the like before the pasting process is performed.

In this manner, the device substrate 600 and the supporting substrate 200 are joined.

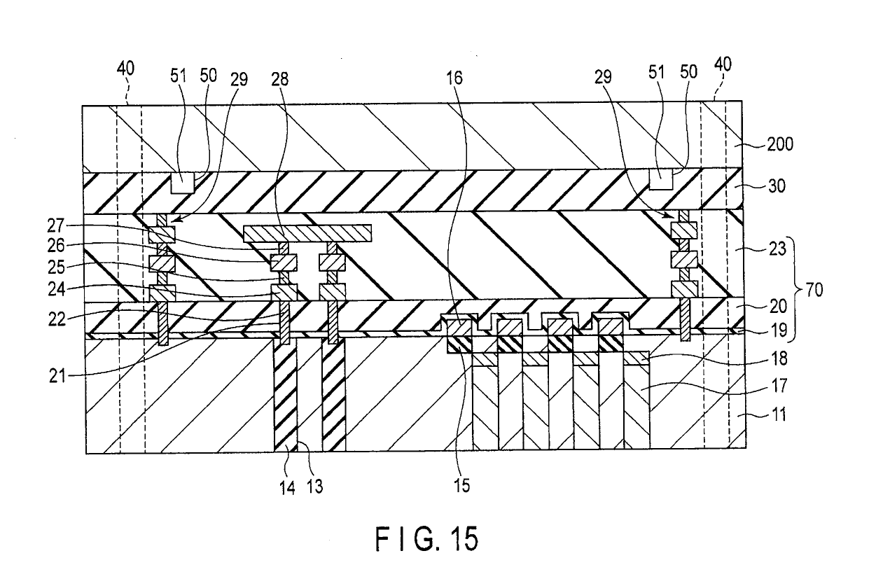

Next, as shown in FIG. 15, the semiconductor substrate 10 is made thinner and removed by BSG (Back Side Grind) or chemical treatment. A solution of fluoric acid/nitric acid, KOH, or TMAH is used as the chemical. In this case, the end point is detected by, for example, an etching stopper layer (not shown) or thickness control of the semiconductor substrate 10. Then, the joined substrate is worked out while the precision of in-plane uniformity, roughness and the like being managed. As the etching stopper layer, a BOX oxide film (not shown) of an SOI wafer (semiconductor substrate 10) or a multilayer epitaxial layer (semiconductor layer 11) with different impurity concentrations is used. Then, the etching stopper layer is removed by RIE or a chemical if necessary.

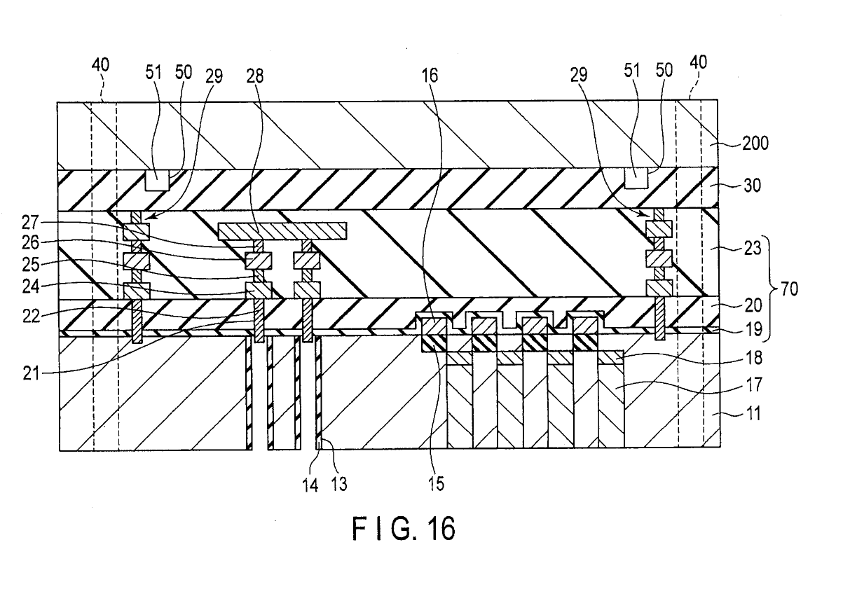

Next, as shown in FIG. 16, a portion of the insulating layer 14 is removed by, for example, photolithography and dry etching in such a way that the insulating layer 14 remains on the side surface of the groove 13. Accordingly, an opening is formed in the insulating layer 14 and the embedded electrode 22 is exposed.

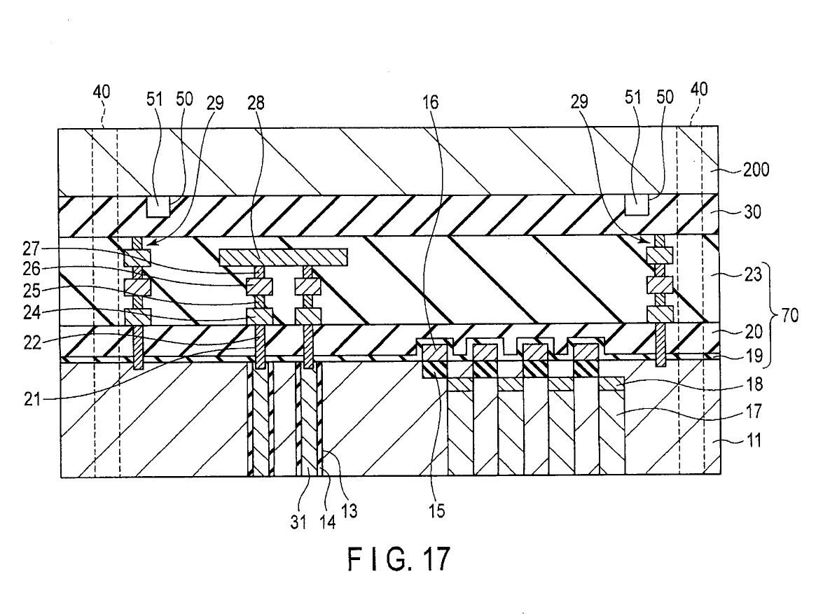

Next, as shown in FIG. 17, the penetrating electrode 31 is formed by, for example, a plating method or the CVD method in such a way that the opening (groove 13) of the insulating layer 14 is filled up. The penetrating electrode 31 is formed of, for example, W, Al, or Cu. Accordingly, the upper surface side and the lower surface side of the semiconductor layer 11 can electrically be connected. Incidentally, the penetrating electrode 31 does not have to fill up the opening of the insulating layer 14 and the upper surface side and the lower surface side of the semiconductor layer 11 may electrically be connected by the penetrating electrode 31 formed on the side surface thereof.

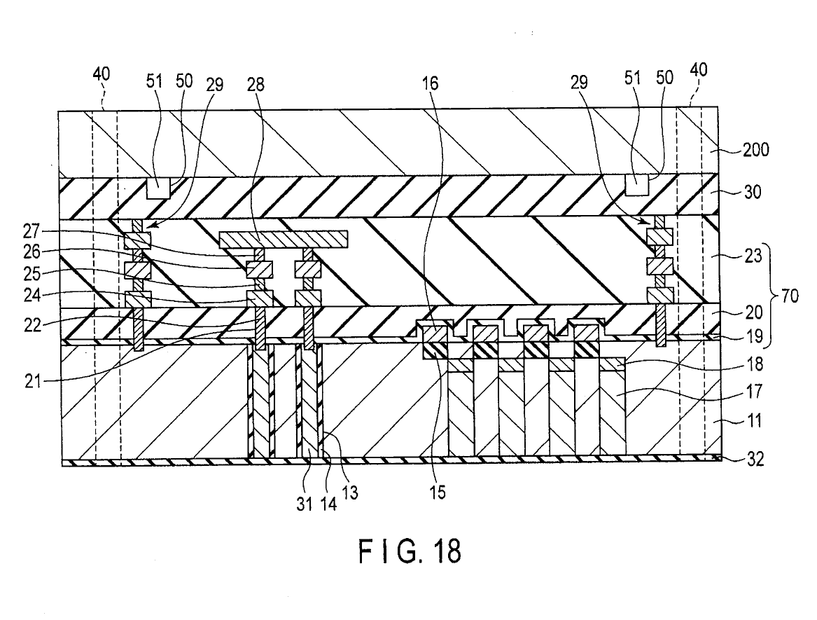

Next, as shown in FIG. 18, the insulating layer 32 is formed on the lower surface of the semiconductor layer 11 by, for example, the CVD method. The insulating layer 32 is formed of, for example, SiO₂.

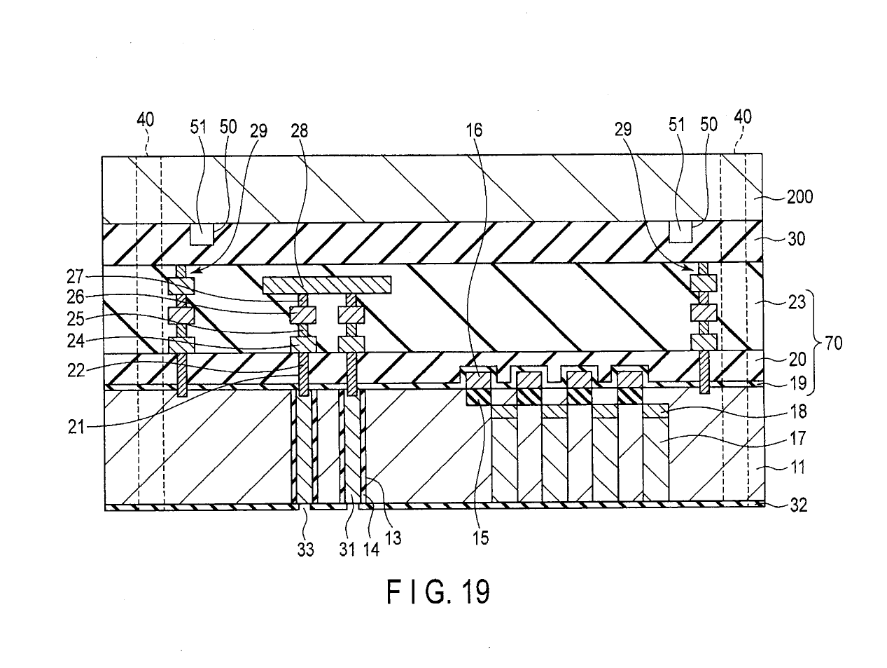

Next, as shown in FIG. 19, the opening 33 is formed in the insulating layer 32 by, for example, photolithography and dry etching. Accordingly, the penetrating electrode 31 is exposed.

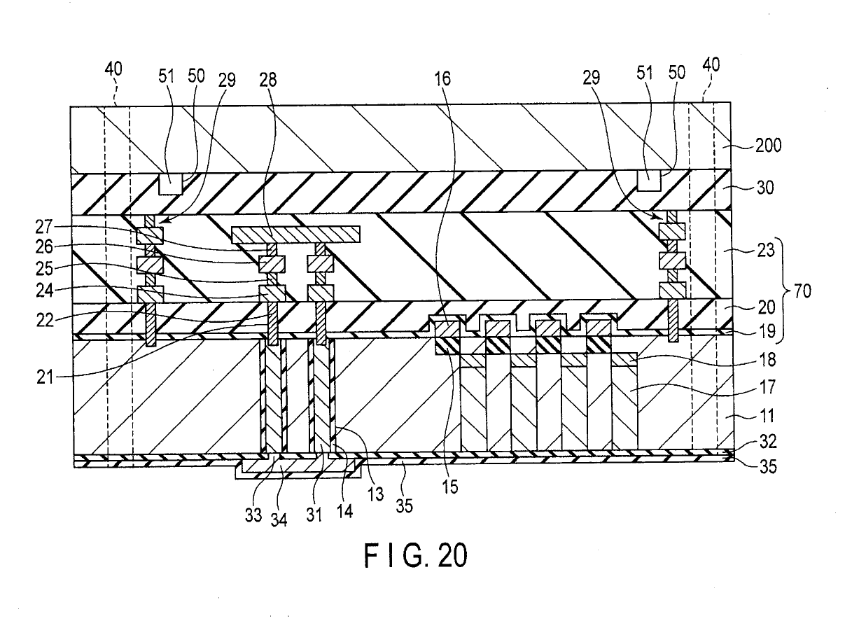

Next, as shown in FIG. 20, the pad 34 connected to the penetrating electrode 31 via the opening 33 is formed below the insulating layer 32. The pad 34 is formed of, for example, Al. The pad 34 is formed just under the penetrating electrode 31 or on the side of the outer circumferential portion from the penetrating electrode 31. Then, the insulating layer 35 is formed on the entire surface of the insulating layer 32 and the pad 34 by, for example, the CVD method. The insulating layer 35 is formed of, for example, SiO₂.

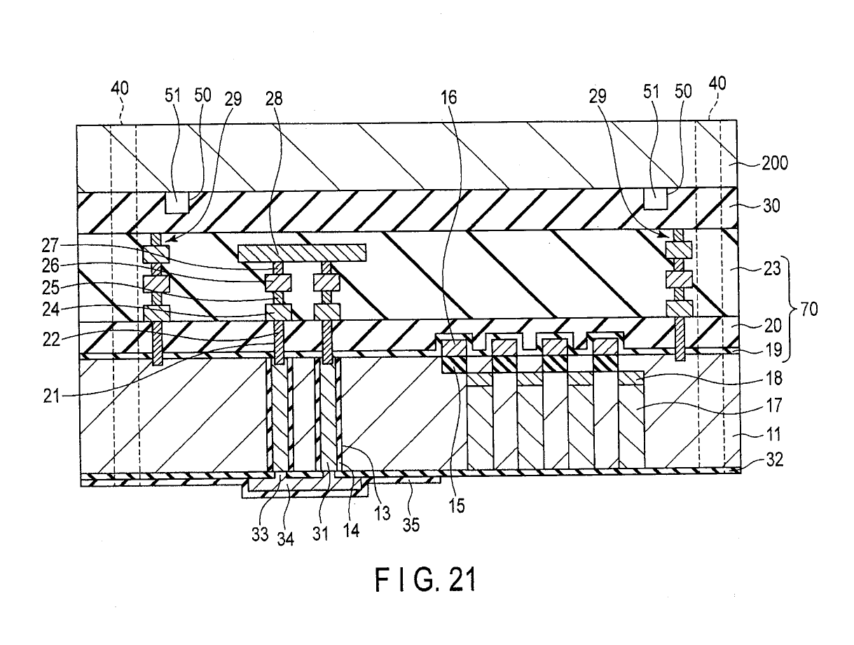

Next, as shown in FIG. 21, a portion of the insulating layer 35 is removed by, for example, photolithography and dry etching to form an opening that exposes the pixel region 300 on the lower surface side of the semiconductor layer 11 in the insulating layer 35.

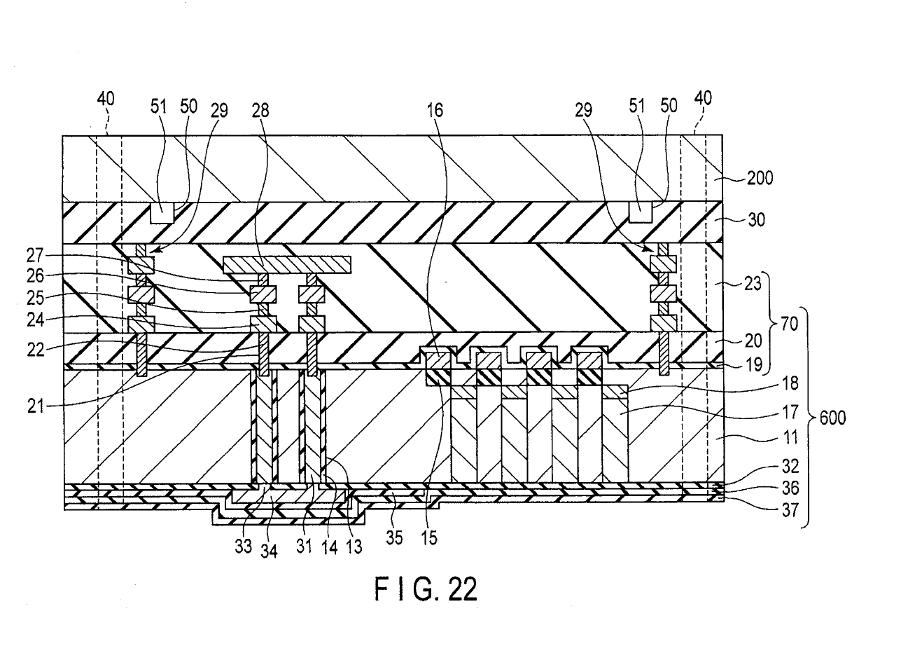

Next, as shown in FIG. 22, the antireflection layers 36, 37 are formed below the semiconductor layer 11 one by one by, for example, the CVD method or a sputtering technique. The antireflection layers 36, 37 are formed of, for example, SiO₂. The antireflection layers 36, 37 have mutually different refractive indexes. Accordingly, reflection of illuminated light can be prevented.

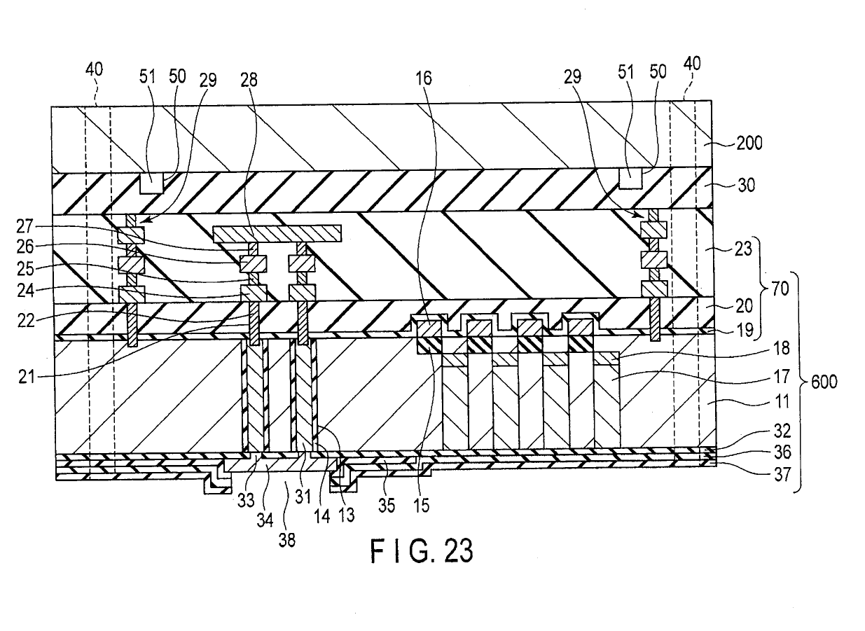

Next, as shown in FIG. 23, a portion of the antireflection layers 36, 37 and the insulating layer 35 is removed by, for example, photolithography and dry etching to form the opening 38 that causes the antireflection layers 36, 37 and the insulating layer 35 to expose the pad 34.

Next, as shown in FIG. 2, after the color filter 39 being formed below the antireflection layer 37 in the pixel region 300 for each pixel, the microlens 41 is formed below the color filter 39 for each pixel. The color filter 39 and the microlens 41 are formed of, for example, transparent organic matter. The color filter 39 can be colored in red, green, or blue.

Next, the supporting substrate 200 is polished from the upper surface side to a thickness of about 200 μm and cut along the dicing line 40 into individual pieces to form the chip 500. In a backside illumination CMOS image sensor having the pasting process, no guard ring is formed in a layer of the joint surface. Thus, horizontal cracks arise in the layer of the joint surface in the dicing process. In the first embodiment, by contrast, development of horizontal cracks during the dicing process can be stopped by providing the groove 50 in the layer (insulating layer 30) of the joint surface in advance. Then, the chip 500 is mounted in a ceramic package or the like, the pad 34 and the package is electrically connected by wire bonding, cover glass is mounted, and plastic molding is performed to complete a semiconductor device according to the first embodiment.

While the groove 13 in which the penetrating electrode 31 is formed is formed before the pasting process, but may also be formed after the pasting process. That is, after the semiconductor substrate 10 being made thinner and removed from the front side, the groove 13, the insulating layer 14, and the penetrating electrode 31 may be formed.

### [Effect]

According to the first embodiment, the insulating layer 30 is formed as a joint surface to the supporting substrate 200 in the device substrate 600 and the insulating layer 30 has the groove 50 in the outer circumferential portion of the chip 500 on the side of the joint surface to the supporting substrate 200. Horizontal cracks generated in the layer (insulating layer 30) of the joint surface from the dicing line 40 during the dicing process can be stopped by the groove 50. Accordingly, generation of unacceptable chips can be limited by preventing film peeling. As a result, improvement of yields and cost reduction in the manufacturing process can be achieved.

### Second Embodiment

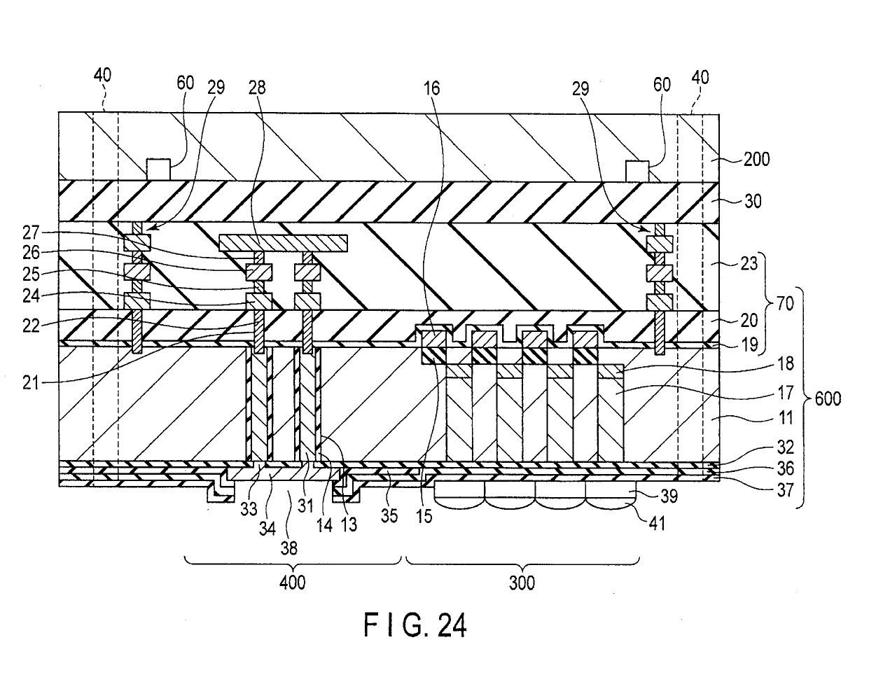

A semiconductor device according to the second embodiment will be described using FIG. 24. The second embodiment is an example in which a supporting substrate 200 has a groove 60 on the inner side of a dicing line (center side of a chip 500) on the joint surface side to a device substrate 600. Accordingly, an occurrence of horizontal cracks to the supporting substrate 200 during the dicing process can be prevented so that damage to the chip 500 can be reduced. The second embodiment will be described in detail below. The description of the second embodiment that is the same as in the first embodiment is omitted and the description focuses mainly on differences.

### [Structure]

First, the structure of a semiconductor device according to the second embodiment will be described using FIG. 24.

FIG. 24 is a sectional view showing the structure of a semiconductor device according to the second embodiment and a sectional view along the A-A line shown in FIG. 1.

As shown in FIG. 24, the second embodiment is different from the first embodiment in that the supporting substrate 200 has the groove 60 in the outer circumferential portion of the chip 500 on the joint surface side to the device substrate 600.

The supporting substrate 200 is joined onto the insulating layer 30 in the device substrate 600. The supporting substrate 200 and the insulating layer 30 are joined by both being pressurized.

The supporting substrate 200 has the groove 60 in the outer circumferential portion of the chip 500. More specifically, the supporting substrate 200 has the groove 60 in the outer circumferential portion of the chip 500 on the joint surface side (lower surface side) to the device substrate 600. That is, the groove 60 is formed in contact with the device substrate 600. In other words, the supporting substrate 200 is not in contact with the device substrate 600 in a position where the groove 60 is formed. The groove 60 may not only be formed on the joint surface side to the device substrate 600, but also extend through the supporting substrate 200 up to the upper surface side thereof.

The groove 60 is positioned on the inner side from a dicing line 40. The groove 60 is also formed just above a guard ring 29 or on the inner side from just above.

The width of the groove 60 is narrower than the width of the dicing line 40. More specifically, the width of the groove 60 is about 10 μm and the width of the dicing line 40 is about 100 μm. The depth of the groove 60 is, for example, 0.1 μm or more and 5 μm or less, thereby preventing an occurrence of cracks.

The groove 60 may be hollow or filled up. Materials with which the groove 60 is filled include, for example, materials that are not joined such as SiN, metallic materials such as Cu and Al, and insulating materials such as TEOS.

### [Manufacturing Method]

Next, the method for manufacturing a semiconductor device according to the second embodiment will be described.

First, like the first embodiment, the processes in FIGS. 3, 4, 5, 6, 7, 8, 9, 10, 11, and 12 are performed. That is, the insulating layer 30 is formed on the interlayer insulating layer 23 in the device substrate 600. Then, the upper surface of the insulating layer 30 is planarized by, for example, CMP. The upper surface of the insulating layer 30 becomes the joint surface to the supporting substrate 200 described later.

Next, as shown in FIG. 24, the groove 60 is formed on the lower surface side of the supporting substrate 200 by, for example, photolithography and dry etching. The groove 60 is formed in the outer circumferential portion of the chip 500 and on the inner side from the dicing line 40. The groove 60 is also formed just above the guard ring 29 or on the inner side from just above. The width of the groove 60 is about a few μm and the depth thereof is 0.1 μm or more and 5 μm or less.

The groove 60 may be hollow or filled up. Materials with which the groove 60 is filled include, for example, materials that are not joined such as SiN, metallic materials such as Cu and Al, and insulating materials such as TEOS.

Next, the supporting substrate 200 in which the groove 60 is formed is joined onto the insulating layer 30 by pasting. At this position, the groove 60 is positioned to be just above the guard ring 29 or on the inner side from just above before being pasted.

The subsequent processes are performed in the same manner as in the first embodiment.

### [Effect]

According to the second embodiment, the supporting substrate 200 has the groove 60 in the outer circumferential portion of the chip 500 on the joint surface side to the device substrate 600. Horizontal cracks generated in the layer (supporting substrate 200) of the joint surface from the dicing line 40 during the dicing process can be stopped by the groove 60. Accordingly, generation of unacceptable chips can be limited by preventing film peeling. As a result, improvement of yields and cost reduction in the manufacturing process can be achieved.

### Third Embodiment

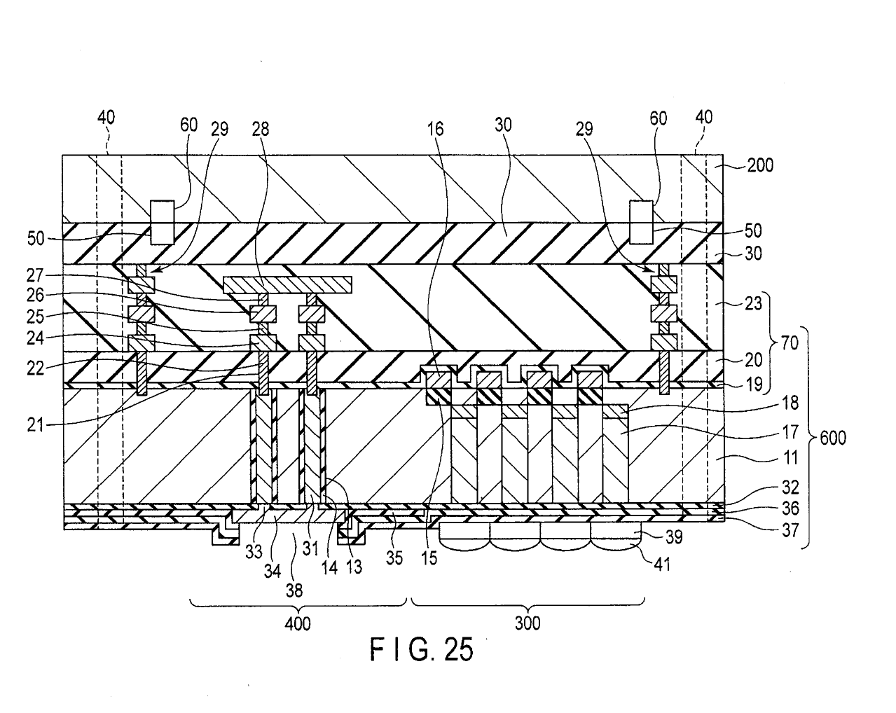

A semiconductor device according to the third embodiment will be described using FIG. 25. The semiconductor device according to the third embodiment is an example in which a device substrate 600 has a groove 50 on the inner side of a dicing line (center side of a chip 500) on the joint surface side to a supporting substrate 200 and the supporting substrate 200 has a groove 60 on the inner side of the dicing line on the joint surface side to the device substrate 600. Accordingly, an occurrence of horizontal cracks to the device substrate 600 and the supporting substrate 200 during dicing process can be prevented so that damage to the chip 500 can be reduced. The third embodiment will be described in detail below. The description of the third embodiment that is the same as in the first embodiment is omitted and the description focuses mainly on differences.

### [Structure]

First, the structure of a semiconductor device according to the third embodiment will be described using FIG. 25.

FIG. 25 is a sectional view showing the structure of a semiconductor device according to the third embodiment and a sectional view along the A-A line shown in FIG. 1.

As shown in FIG. 25, the third embodiment is different from the first embodiment in that the device substrate 600 has the groove 50 in the outer circumferential portion of the chip 500 on the joint surface side to the supporting substrate 200 and the supporting substrate 200 has the groove 60 in the outer circumferential portion of the chip 500 on the joint surface side to the device substrate 600.

The supporting substrate 200 is joined onto the insulating layer 30 in the device substrate 600. The supporting substrate 200 and the insulating layer 30 are joined by both being pressurized.

The device substrate 600 has the groove 50 in the outer circumferential portion of the chip 500. More specifically, the device substrate 600 has the groove 50 in the outer circumferential portion of the chip 500 on the joint surface side (upper surface side) to the supporting substrate 200. That is, the device substrate 600 is not in contact with the supporting substrate 200 in a position where the groove 50 is formed. The groove 50 may not only be formed on the joint surface side to the supporting substrate 200, but also extend through the device substrate 600 up to the lower surface side thereof.

On the other hand, the supporting substrate 200 has the groove 60 in the outer circumferential portion of the chip 500. More specifically, the supporting substrate 200 has the groove 60 in the outer circumferential portion of the chip 500 on the joint surface side (lower surface side) to the device substrate 600. That is, the supporting substrate 200 is not in contact with the device substrate 600 in a position where the groove 60 is formed. The groove 60 may not only be formed on the joint surface side to the device substrate 600, but also extend through the supporting substrate 200 up to the upper surface side thereof.

The grooves 50, 60 are positioned on the inner side from a dicing line 40. The grooves 50, 60 are also formed just above a guard ring 29 or on the inner side from just above. The grooves 50, 60 are formed mutually in the same position and overlap each other when viewed from above. That is, the grooves 50, 60 are in contact with each other. The grooves 50, 60 are desirably formed in the same position, but may not be formed in the same position.

The widths of the grooves 50, 60 are narrower than the width of the dicing line 40. The width of the groove 50 is narrower than the width of the groove 60. More specifically, the width of the groove 50 is about a few μm, the width of the groove 60 is about 10 μm, and the width of the dicing line 40 is about 100 μm. By making the width of the groove 50 narrower than the width of the groove 60, the positioning margin to cause the grooves 50, 60 to overlap can be improved in the pasting process. The depth of the grooves 50, 60 is 0.1 μm or more and 5 μm or less, thereby preventing an occurrence of cracks. Incidentally, the width of the groove 60 may be made narrower than the width of the groove 50.

The grooves 50, 60 may be hollow or filled up. Materials with which the grooves 50 60 are filled include, for example, materials that are not joined such as SiN, metallic materials such as Cu and Al, and insulating materials such as TEOS.

### [Manufacturing Method]

Next, the method for manufacturing a semiconductor device according to the third embodiment will be described.

First, like the first embodiment, the processes in FIGS. 3, 4, 5, 6, 7, 8, 9, 10, 11 and 12 are performed. That is, the insulating layer 30 is formed on the interlayer insulating layer 23 in the device substrate 600. Then, the upper surface of the insulating layer 30 is planarized by, for example, CMP. The upper surface of the insulating layer 30 becomes the joint surface to the supporting substrate 200 described later.

Next, as shown in FIG. 25, the groove 50 is formed on the upper surface side of the device substrate 600 (insulating layer 30) by, for example, photolithography and dry etching. The groove 50 is formed in the outer circumferential portion of the chip 500 and on the inner side from the dicing line 40. The groove 50 is also formed just above the guard ring 29 or on the inner side from just above. The width of the groove 50 is about a few μm and the depth thereof is 0.1 μm or more and 5 μm or less.

Further, the groove 60 is formed on the lower surface side of the supporting substrate 200 by, for example, photolithography and dry etching. The groove 60 is formed in the outer circumferential portion of the chip 500 and on the inner side from the dicing line 40. The groove 60 is also formed just above a guard ring 29 or on the inner side from just above. The width of the groove 60 is about 10 μm and the depth thereof is 0.1 μm or more and 5 μm or less.

The grooves 50, 60 may be hollow or filled up. Materials with which the grooves 50 60 are filled include, for example, materials that are not joined such as SiN, metallic materials such as Cu and Al, and insulating materials such as TEOS.

Next, the supporting substrate 200 in which the groove 60 is formed is joined onto the insulating layer 30 in which the groove 50 is formed by pasting. At this point, the grooves 50, 60 are positioned to be in the same position (to overlap) before being joined.

The subsequent processes are performed in the same manner as in the first embodiment.

### [Effect]

According to the third embodiment, the device substrate 600 has the groove 50 in the outer circumferential portion of the chip 500 on the joint surface side to the supporting substrate 200 and the supporting substrate 200 has the groove 60 in the outer circumferential portion of the chip 500 on the joint surface side to the device substrate 600. Horizontal cracks generated in the layers (the insulating layer 30 and the supporting substrate 200) of the joint surface from the dicing line 40 during the dicing process can be stopped by the grooves 50, 60. Accordingly, generation of unacceptable chips can further be limited by preventing film peeling. As a result, improvement of yields and cost reduction in the manufacturing process can further be achieved.

### Fourth Embodiment

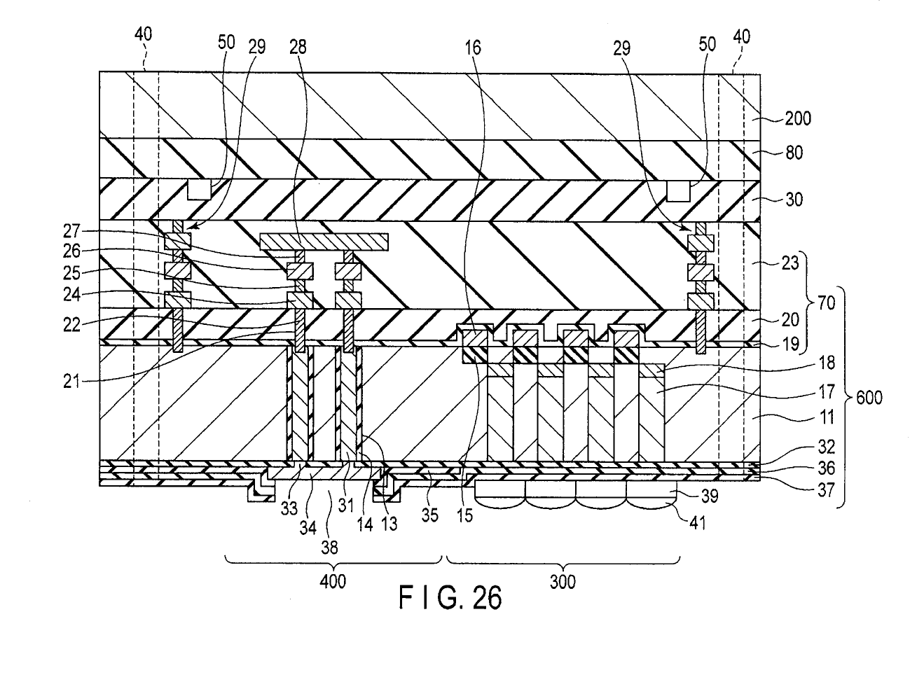

A semiconductor device according to the fourth embodiment will be described using FIG. 26. The fourth embodiment is an example in which an insulating layer 80 whose surface is planarized is formed as the joint surface of a supporting substrate 200. Accordingly, the bonding strength of the supporting substrate 200 and a device substrate 600 can be increased. The fourth embodiment will be described in detail below. The description of the fourth embodiment that is the same as in the first embodiment is omitted and the description focuses mainly on differences.

### [Structure]

First, the structure of a semiconductor device according to the fourth embodiment will be described using FIG. 26.

FIG. 26 is a sectional view showing the structure of a semiconductor device according to the fourth embodiment and a sectional view along the A-A line shown in FIG. 1.

As shown in FIG. 26, the fourth embodiment is different from the first embodiment in that the supporting substrate 200 has the insulating layer 80 to be the joint surface to the device substrate 600 on the front side (lower surface) thereof.

The insulating layer 80 is formed as a joint surface to the device substrate 600 on the lower surface of the supporting substrate 200 and joined onto an insulating layer 30 in the device substrate 600. The insulating layer 80 and the insulating layer 30 are joined by both being pressurized.

The insulating layer 80 is formed of, for example, an oxide film. More specifically, the insulating layer 80 is formed of, for example, an SiO₂ film using TEOS or the like as a material, an SiO₂ film by thermal oxidation or a low-k film. The thickness of the insulating layer 80 is 0.1 μm or more and 5 μm or less.

### [Manufacturing Method]

Next, the method for manufacturing a semiconductor device according to the fourth embodiment will be described.

First, like the first embodiment, the processes in FIGS. 3, 4, 5, 6, 7, 8, 9, 10, 11 and 12 are performed. That is, the insulating layer 30 is formed on the interlayer insulating layer 23 in the device substrate 600. Then, the upper surface of the insulating layer 30 is planarized by, for example, CMP. The upper surface of the insulating layer 30 becomes the joint surface to the insulating layer 80 described later.

Next, as shown in FIG. 26, a groove 50 is formed on the upper surface side of the device substrate 600 (insulating layer 30) by, for example, photolithography and dry etching. The groove 50 is formed in the outer circumferential portion of the chip 500 and on the inner side from a dicing line 40. The groove 50 is also formed just above a guard ring 29 or on the inner side from just above. The width of the groove 50 is about a few μm and the depth thereof is 0.1 μm or more and 5 μm or less.

The groove 50 may be hollow or filled up. Materials with which the groove 50 is filled include, for example, materials that are not joined such as SiN, metallic materials such as Cu and Al, and insulating materials such as TEOS.

The insulating layer 80 is formed on the lower surface of the supporting substrate 200 (front side on the joint surface side). The insulating layer 80 is formed of, for example, an oxide film. More specifically, the insulating layer 80 is formed of an SiO₂ film or a low-k film. The insulating layer 80 is formed by various methods such as thermal oxidation, the CVD method, the ALD method, the application process or the like.

Then, the lower surface of the insulating layer 80 is planarized by, for example, CMP. The lower surface of the insulating layer 80 becomes the joint surface to the device substrate 600 (insulating layer 30) described later. By planarizing the lower surface of the insulating layer 80, the bonding strength between the insulating layer 80 and the insulating layer 30 can be improved.

Next, the supporting substrate 200 (insulating layer 80) is joined onto the insulating layer 30 in which the groove 50 is formed by pasting.

The subsequent processes are performed in the same manner as in the first embodiment.

### [Effect]

According to the fourth embodiment, effects similar to effects in the first embodiment can be obtained.

Further in the fourth embodiment, the insulating layer 80 whose surface is planarized is formed as the joint surface of the supporting substrate 200. Accordingly, the bonding strength of the supporting substrate 200 and the device substrate 600 can be increased.

### Fifth Embodiment

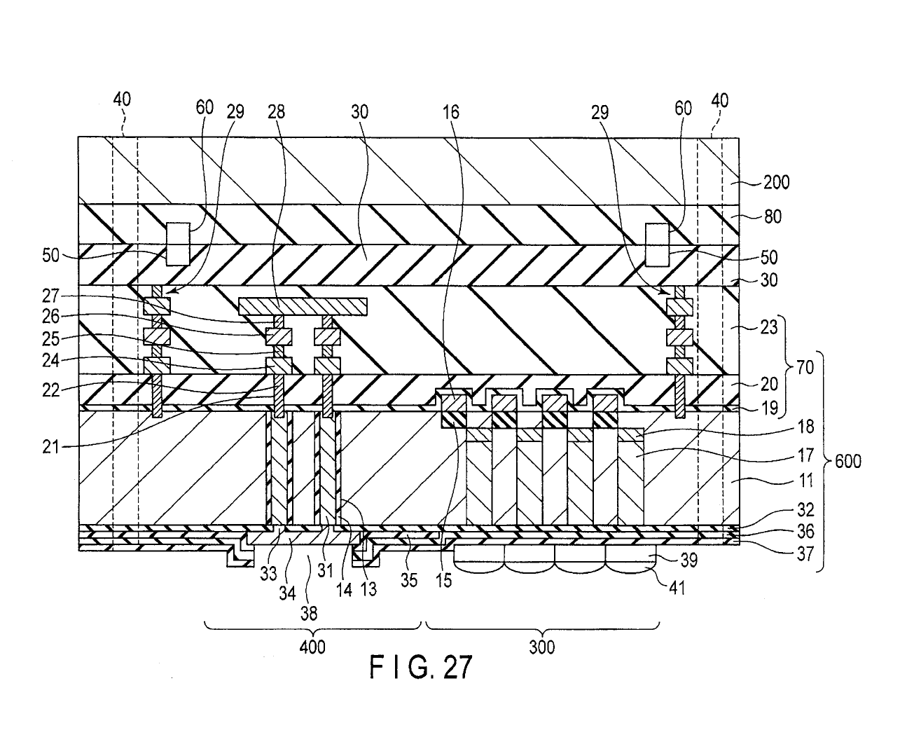

A semiconductor device according to the fifth embodiment will be described using FIG. 27. The fifth embodiment is an example in which an insulating layer 80 whose surface is planarized is formed as the joint surface of a supporting substrate 200 and the insulating layer 80 has a groove 60 on the inner side of a dicing line on the joint surface side to a device substrate 600. The fifth embodiment will be described in detail below. The description of the fifth embodiment that is the same as in the first embodiment is omitted and the description focuses mainly on differences.

### [Structure]

First, the structure of a semiconductor device according to the fifth embodiment will be described using FIG. 27.

FIG. 27 is a sectional view showing the structure of a semiconductor device according to the fifth embodiment and a sectional view along the A-A line shown in FIG. 1.

As shown in FIG. 27, the fifth embodiment is different from the first embodiment in that the supporting substrate 200 has the insulating layer 80 to be the joint surface to the device substrate 600 on the front side (lower surface) thereof and the insulating layer 80 has the groove 60 in the outer circumferential portion of a chip 500 on the joint surface side to the device substrate 600.

The insulating layer 80 is formed as a joint surface to the device substrate 600 on the lower surface of the supporting substrate 200 and joined onto an insulating layer 30 in the device substrate 600. The insulating layer 80 and the insulating layer 30 are joined by both being pressurized.

The insulating layer 80 is formed of, for example, an oxide film. More specifically, the insulating layer 80 is formed of, for example, an SiO₂ film using TEOS or the like as a material, an SiO₂ film by thermal oxidation or a low-k film. The thickness of the insulating layer 80 is 0.1 μm or more and 5 μm or less.

The device substrate 600 has a groove 50 in the outer circumferential portion of the chip 500. More specifically, the device substrate 600 has the groove 50 in the outer circumferential portion of the chip 500 on the joint surface side (upper surface side) to the supporting substrate 200. That is, the device substrate 600 is not in contact with the supporting substrate 200 in a position where the groove 50 is formed. The groove 50 may not only be formed on the joint surface side to the supporting substrate 200, but also extend through the device substrate 600 up to the lower surface side thereof.

On the other hand, the insulating layer 80 formed as the joint surface to the device substrate 600 on the lower surface of the supporting substrate 200 has the groove 60 in the outer circumferential portion of the chip 500. More specifically, the insulating layer 80 has the groove 60 in the outer circumferential portion of the chip 500 on the joint surface side (lower surface side) to the device substrate 600. That is, the insulating layer 80 is not in contact with the device substrate 600 in a position where the groove 60 is formed. The groove 60 may not only be formed on the joint surface side to the device substrate 600, but also extend through the insulating layer 80 up to the upper surface side thereof.

The grooves 50, 60 are positioned on the inner side from a dicing line 40. The grooves 50, 60 are also formed just above a guard ring 29 or on the inner side from just above. The grooves 50, 60 are desirably formed mutually in the same position and overlap each other when viewed from above, but the present embodiment is not limited to this example.

The widths of the grooves 50, 60 are narrower than the width of the dicing line 40. The width of the groove 50 is narrower than the width of the groove 60. More specifically, the width of the groove 50 is about a few μm, the width of the groove 60 is about 10 μm, and the width of the dicing line 40 is about 100 μm. By making the width of the groove 50 narrower than the width of the groove 60, the positioning margin to cause the grooves 50, 60 to overlap can be improved in the pasting process. The depth of the grooves 50, 60 is 0.1 μm or more and 5 μm or less, thereby preventing an occurrence of cracks. Incidentally, the width of the groove 60 may be made narrower than the width of the groove 50.

The grooves 50, 60 may be hollow or filled up. Materials with which the grooves 50 60 are filled include, for example, materials that are not joined such as SiN, metallic materials such as Cu and Al, and insulating materials such as TEOS.

### [Manufacturing Method]

Next, the method for manufacturing a semiconductor device according to the fifth embodiment will be described.

First, like the first embodiment, the processes in FIGS. 3, 4, 5, 6, 7, 8, 9, 10, 11 and 12 are performed. That is, the insulating layer 30 is formed on the interlayer insulating layer 23 in the device substrate 600. Then, the upper surface of the insulating layer 30 is planarized by, for example, CMP. The upper surface of the insulating layer 30 becomes the joint surface to the insulating layer 80 described later.

Next, as shown in FIG. 27, the groove 50 is formed on the upper surface side of the device substrate 600 (insulating layer 30) by, for example, photolithography and dry etching. The groove 50 is formed in the outer circumferential portion of the chip 500 and on the inner side from the dicing line 40. The groove 50 is also formed just above the guard ring 29 or on the inner side from just above. The width of the groove 50 is about a few μm and the depth thereof is 0.1 μm or more and 5 μm or less.

The insulating layer 80 is formed on the lower surface of the supporting substrate 200 (front side on the joint surface side). The insulating layer 80 is formed of, for example, an oxide film. More specifically, the insulating layer 80 is formed of an SiO₂ film or a low-k film. The insulating layer 80 is formed by various methods such as thermal oxidation, the CVD method, the ALD method, the application process or the like.

Then, the groove 60 is formed on the lower surface side of the insulating layer 80 by, for example, photolithography and dry etching. The groove 60 is formed in the outer circumferential portion of the chip 500 and on the inner side from the dicing line 40. The groove 60 is also formed just above the guard ring 29 or on the inner side from just above. The width of the groove 60 is about 10 μm and the depth thereof is 0.1 μm or more and 5 μm or less.

The grooves 50, 60 may be hollow or filled up. Materials with which the grooves 50 60 are filled include, for example, materials that are not joined such as SiN, metallic materials such as Cu and Al, and insulating materials such as TEOS.

Next, the insulating layer 80 in which the groove 60 is formed is joined onto the insulating layer 30 in which the groove 50 is formed by pasting. At this point, the grooves 50, 60 are positioned to be in the same position (to overlap) before being joined.

The subsequent processes are performed in the same manner as in the first embodiment.

### [Effect]

According to the fifth embodiment, effects similar to effects in the third embodiment and the fourth embodiment can be obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a device substrate; and
a supporting substrate joined onto the device substrate,
wherein the device substrate comprises a first groove in an outer circumferential portion on a joint surface side to the supporting substrate.

2. The device of claim 1, wherein
the supporting substrate comprises a second groove in the outer circumferential portion on the joint surface side to the device substrate.

3. The device of claim 1, wherein
the device substrate comprises a first insulating layer to be a joint surface to the supporting substrate, and
the first groove is formed in the first insulating layer.

4. The device of claim 1, wherein
the device substrate comprises:
a semiconductor layer formed below the supporting substrate and comprising light receiving units that stores charges by making a signal conversion of light illuminated from below; and
a wiring layer formed below the supporting substrate and on the semiconductor layer and comprising a circuit unit that reads the charges stored in the light receiving units.

5. The device of claim 3, wherein
the first insulating layer comprises one of a silicon oxide film and a low-k film.

6. The device of claim 3, wherein
the first groove is formed so as to extend through the first insulating layer.

7. The device of claim 4, wherein
the wiring layer comprises a guard ring in the outer circumferential portion.

8. The device of claim 7, wherein
the first groove is formed just above the guard ring.

9. The device of claim 1, wherein
the first groove is hollow or filled with a material that is different from the material therearound.

10. The device of claim 2, wherein
the second groove is formed just above the first groove.

11. The device of claim 2, wherein
the second groove is hollow or filled with a material that is different from the material therearound.

12. The device of claim 2, wherein
the second groove is formed so as to extend through the supporting substrate.

13. The device of claim 1, wherein
the supporting substrate comprises a second insulating layer to be a joint surface to the device substrate.

14. The device of claim 2, wherein
the supporting substrate comprises a second insulating layer to be a joint surface to the device substrate, and
the second groove is formed in the second insulating layer.

15. The device of claim 14, wherein
the second groove is formed so as to extend through the second insulating layer.

16. A semiconductor device comprising:
a device substrate comprising a guard ring in an outer circumferential portion thereof; and
a supporting substrate joined onto the device substrate,
wherein the supporting substrate comprises a groove in an outer circumferential portion on a joint surface side to the device substrate and on an inner side from the guard ring.

17. The device of claim 16, wherein
the device substrate comprises:
a semiconductor layer formed below the supporting substrate and comprising light receiving units that stores charges by making a signal conversion of light illuminated from below; and
a wiring layer formed below the supporting substrate and on the semiconductor layer and comprising a circuit unit that reads the charges stored in the light receiving units.

18. The device of claim 16, wherein
the groove is formed so as to extend through the supporting substrate.

19. The device of claim 17, wherein
the groove is hollow or filled with a material that is different from the material therearound.

20. A method of manufacturing a semiconductor device, comprising:
forming a groove in an outer circumferential portion of a chip on a joint surface side to a device substrate and on an inner side of a dicing line;
joining a supporting substrate to the joint surface side to the device substrate; and
dicing the joined device substrate and supporting substrate along the dicing line.
